(19) United States
(12) Patent Application Publication
(10) Pub. No.: US 2006/0267115 A1
(43) Pub. Date: Nov. 30, 2006

(54) Semiconductor device and method of manufacturing the same

(75) Inventors: Toru Takeguchi, Tokyo (JP); Kaoru Motonami, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Chiyoda-ku (JP)

(21) Appl. No.: 11/366,538

(22) Filed: Mar. 3, 2006

(30) Foreign Application Priority Data
May 24, 2005 (JP) 2005-150769

(51) Int. Cl. H01L 29/94

(52) U.S. Cl. 257/411

(57) ABSTRACT

A gate insulating film of a thin-film transistor is formed on a polysilicon film in which a source region and a drain region of the thin-film transistor are formed. A gate electrode of the thin-film transistor is formed on the gate insulating film. An insulating layer containing a silicon atom, a dangling bond of which is terminated with a nitrogen atom or an ON group, is provided in an interface between the polysilicon film and the gate insulating film.

### BACKGROUND OF THE INVENTION

1. Field of the Invention

The present invention relates to a semiconductor device including a transistor which includes a source region and a drain region formed in a polysilicon film, and to a method of manufacturing the same.

2. Description of the Background Art

In a display device with an incorporated drive circuit, a thin-film transistor including a source region and a drain region which are formed in a polysilicon film is used as a switching element. According to one of well-known methods of forming such a polysilicon film, an amorphous silicon film is deposited on a glass substrate, and subsequently, is annealed using an excimer laser, to be crystallized. Then, to form a thin-film transistor, such a polysilicon film as formed in the above-mentioned manner is patterned so that the polysilicon film is shaped like an island, and a silicon oxide film formed by using a TEOS gas is formed on the island-shaped polysilicon film, to serve as a gate insulating film.

The above-described conventional manufacturing method, however, would suffer from occurrence of numerous defects in the polysilicon film or an interface between the polysilicon film and the gate insulating film. In order to reduce the defects, Japanese Patent Application Laid-Open No. 11-307775 (which will hereinafter be referred to as “JP No. 11-307775”) employs a method in which a hydrogen plasma treatment is performed on the polysilicon film to fill the defects with hydrogen atoms. By this method, the defects occurring in the polysilicon film or the interface between the polysilicon film and the gate insulating film are reduced, to thereby improve rise characteristics in Id-Vg characteristics or an on-state current of the thin-film transistor.

Also, what is called a “resist diminishing method” in which a resist film is gradually etched during an etching process performed on an etching target film using the resist film as a mask, to slant a side face of the etching target film, is disclosed in Japanese Patent Application Laid-Open No. 2001-168343, for example.

However, in a case where a thin-film transistor is manufactured by the above-described manufacturing method disclosed in JP No. 11-307775, a bond between a silicon atom and a hydrogen atom may probably be broken because of its weakness in continuous operation of the thin-film transistor, resulting in changes in the transistor characteristics of the thin-film transistor, though the method disclosed by JP No. 11-307775 can improve the initial characteristics of the thin-film transistor. For example, an on-state current reduces, or a threshold voltage changes. Accordingly, the thus-formed conventional thin-film transistor cannot achieve proper performance in some cases.

Further, in the conventional thin-film transistor, a breakdown voltage of a gate cannot be easily improved. Also in this aspect, the conventional thin-film transistor cannot achieve proper performance in some cases.

### SUMMARY OF THE INVENTION

It is an object of the present invention to provide a technique which allows improvement of performance of a transistor including a source region and a drain region which are formed in a polysilicon film.

A first semiconductor device according to the present invention including a transistor includes a polysilicon film, a gate insulating film of the transistor, and a gate electrode of the transistor. In the polysilicon film, a source region and a drain region of the transistor are formed. The gate insulating film is formed on the polysilicon film. The gate electrode is formed on the gate insulating film. Further, an insulating layer containing a silicon atom, a dangling bond of which is terminated with a nitrogen atom or an ON group, is provided in an interface between the polysilicon film and the gate insulating film.

In the first semiconductor device, the insulating layer containing a silicon atom, a dangling bond of which is terminated with a nitrogen atom or an ON group. As a bonding energy provided between a silicon atom and a nitrogen atom is greater than a bonding energy provided between a silicon atom and a hydrogen atom, a bond between a silicon atom and a nitrogen atom is not easily broken. Likewise, as a bonding energy provided between a silicon atom and an ON group is greater than a bonding energy provided between a silicon atom and a hydrogen atom, a bond between a silicon atom and an ON group is not easily broken. Accordingly, even in continuous operation of the transistor, changes in the transistor characteristics can be suppressed, to thereby improve performance of the transistor.

A second semiconductor device according to the present invention including a transistor includes a polysilicon film, a gate insulating film of the transistor, and a gate electrode of the transistor. In the polysilicon film, a source region and a drain region of the transistor are formed. The gate insulating film is formed on the polysilicon film. The gate electrode is formed on the gate insulating film. The polysilicon film has a tapered sectional shape in which a width of the polysilicon film becomes smaller as a distance to the gate insulating film decreases, and a gradient of the polysilicon film is equal to or smaller than 60 degrees.

By setting the gradient of the polysilicon film at 60 degrees or smaller, it is possible to improve a breakdown voltage of a gate of the transistor.

A method of manufacturing a semiconductor device according to the present invention is directed to a method of manufacturing a semiconductor device including a transistor. The method includes steps (a), (b), (c), (d), and (e). The step (a) is to form a polysilicon film. The step (b) is to terminate a dangling bond of a silicon atom existing in a surface of the polysilicon film with a nitrogen atom or an ON group. The step (c) is to form a gate insulating film of the transistor on the polysilicon film after the step (b). The step (d) is to form a source region and a drain region of the transistor in the polysilicon film. The step (e) is to form a gate electrode of the transistor on the gate insulating film.

In the method of manufacturing a semiconductor device according to the present invention, a dangling bond of a silicon atom existing in the surface of the polysilicon film is terminated with a nitrogen atom or an ON group. As a bonding energy provided between a silicon atom and a nitrogen atom is greater than a bonding energy provided between a silicon atom and a hydrogen atom, a bond provided between a silicon atom and a nitrogen atom is not easily broken. Likewise, as a bonding energy between a silicon atom and an ON group is greater than a bonding energy provided between a silicon atom and a hydrogen atom, a bond between a silicon atom and an ON group is not easily broken. Accordingly, even in continuous operation of the transistor, changes in the transistor characteristics can be suppressed, to thereby improve performance of the transistor.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a structure of a semiconductor device according to one preferred embodiment of the present invention.

FIG. 2 is an enlarged sectional view of a portion of the structure of the semiconductor device according to the preferred embodiment of the present invention.

FIGS. 3 through 10 are sectional views for explaining respective steps of a method of manufacturing a semiconductor device according to one preferred embodiment of the present invention in order of performance of the steps.

FIG. 11 is an enlarged sectional view of a portion of a structure according to a modification of the semiconductor device according to the preferred embodiment of the present invention.

FIG. 12 is a graph showing a relationship between a gradient of a polysilicon film and a gate breakdown voltage of a thin-film transistor.

### DESCRIPTION OF THE PREFERRED EMBODIMENTS

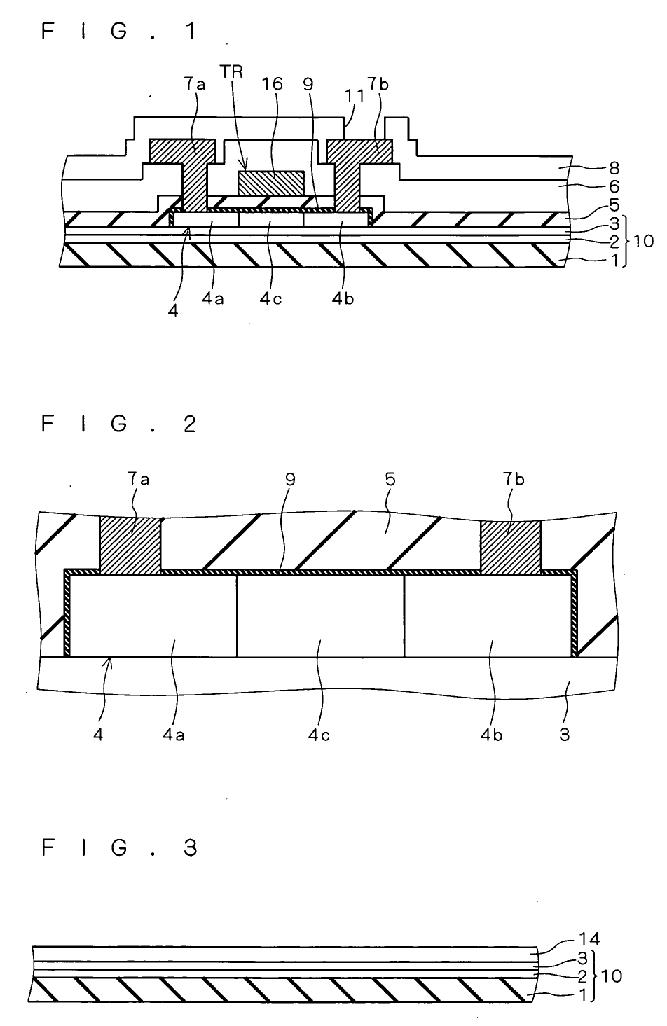

FIG. 1 is a sectional view of a structure of a semiconductor device according to one preferred embodiment of the present invention. FIG. 2 is an enlarged sectional view of a portion of the structure of the semiconductor device according to the preferred embodiment of the present invention. The semiconductor device according to the preferred embodiment of the present invention is used as a drive circuit incorporated in a liquid crystal panel, for example, and includes an n-type thin-film transistor TR serving as a switching element.

As illustrated in FIG. 1, the semiconductor device according to the preferred embodiment of the present invention includes an insulating layer 10. The insulating layer 10 includes an insulating substrate 1 including a glass substrate, for example, an insulating film 2 formed on the insulating substrate 1, and an insulating film 3 formed on the insulating film 2. Each of the insulating films 2 and 3 is light permeable. The insulating films 2 and 3 are a silicon nitride film and a silicon oxide film, respectively, for example.

A polysilicon film 4 is formed on a region of the insulating film 3 of the insulating layer 10. In the polysilicon film 4, a source region 4a and a drain region 4b of the thin-film transistor TR are formed with a predetermined distance being left therebetween. A gate insulating film 5 of the thin-film transistor TR is formed on the insulating layer 10 so as to cover the polysilicon film 4. As illustrated in FIG. 2, an extremely thin insulating layer 9 is provided in an interface between the polysilicon film 4 and the gate insulating film 5. The insulating layer 9 contains a silicon atom, a dangling bond of which is terminated with a nitrogen atom or an ON group.

A gate electrode 16 of the thin-film transistor TR is formed on a region of the gate insulating film 5, being located above a region interposed between the source region 4a and the drain region 4b in the polysilicon film 4. Accordingly, the region interposed between the source region 4a and the drain region 4b in the polysilicon film 4 serves as a channel region 4c of the thin-film transistor TR.

An interlayer insulating film 6 is formed on the gate insulating film 5 so as to cover the gate electrode 16. A source electrode 7a and a drain electrode 7b which pass through the interlayer insulating film 6, the gate insulating film 5, and the insulating layer 9 and reach the source region 4a and the drain region 4b, respectively, are formed in the interlayer insulating film 6, the gate insulating film 5, and the insulating layer 9. Also, each of the source electrode 7a and the drain electrode 7b includes a portion formed on the interlayer insulating film 6. Further, an insulating film 8 is formed on the interlayer insulating film 6 so as to cover the portions of the source electrode 7a and the drain electrode 7b which are located on the interlayer insulating film 6 and thus are exposed. Moreover, a contact hole 11 which passes through the insulating film 8 and reaches the drain electrode 7b is formed in the insulating film 8. The contact hole 11 is used for electrically connecting a pixel electrode (not illustrated) of the liquid crystal panel and the drain electrode 7b of the thin-film transistor TR, and applying a voltage of the drain electrode 7b to the pixel electrode.

Each of the gate insulating film 5, the interlayer insulating film 6, and the insulating film 8 includes a silicon oxide film, for example. The gate electrode 16 includes a chromium film, a metal film which contains a metal having a high melting point such as a molybdenum film, or a polysilicon film, for example. Each of the source electrode 7a and the drain electrode 7b includes a metal film such as an aluminum alloy film, a chromium film, a molybdenum film, or a stack of such films, for example.

As described above, the semiconductor device according to the preferred embodiment of the present invention includes the insulating layer 9 containing a silicon atom, a dangling bond of which is terminated with a nitrogen atom or an ON group. A bonding energy provided between a silicon atom and a nitrogen atom is greater than a bonding energy provided between a silicon atom and a hydrogen atom. Accordingly, a bond between a silicon atom and a nitrogen atom is not easily broken. Likewise, a bonding energy provided between a silicon atom and an ON group is greater than a bonding energy provided between a silicon atom and a hydrogen atom. Accordingly, a bond between a silicon atom and an ON group is not easily broken. Therefore, even in continuous operation of the thin-film transistor TR, changes in the transistor characteristics thereof such as reduction of an on-state current or a change in a threshold voltage can be suppressed, to thereby improve performance of the thin-film transistor TR.

Below, a method of manufacturing the semiconductor device according to the preferred embodiment of the present invention which is illustrated in FIGS. 1 and 2 will be described in detail. FIGS. 3, 4, 5, 6, 7, 8, 9, and 10 are sectional views for explaining respective steps of the method of manufacturing a semiconductor device according to one preferred embodiment of the present invention in order of performance of the steps. It is noted that FIG. 6 is an enlarged sectional view of a portion of the semiconductor device according to the preferred embodiment of the present invention which is being manufactured.

First, as illustrated in FIG. 3, the light-permeable insulating films 2 and 3 are deposited on the insulating substrate 1, and subsequently the amorphous silicon film 14 is deposited on the insulating film 3, by a plasma CVD (chemical vapor deposition) process, for example.

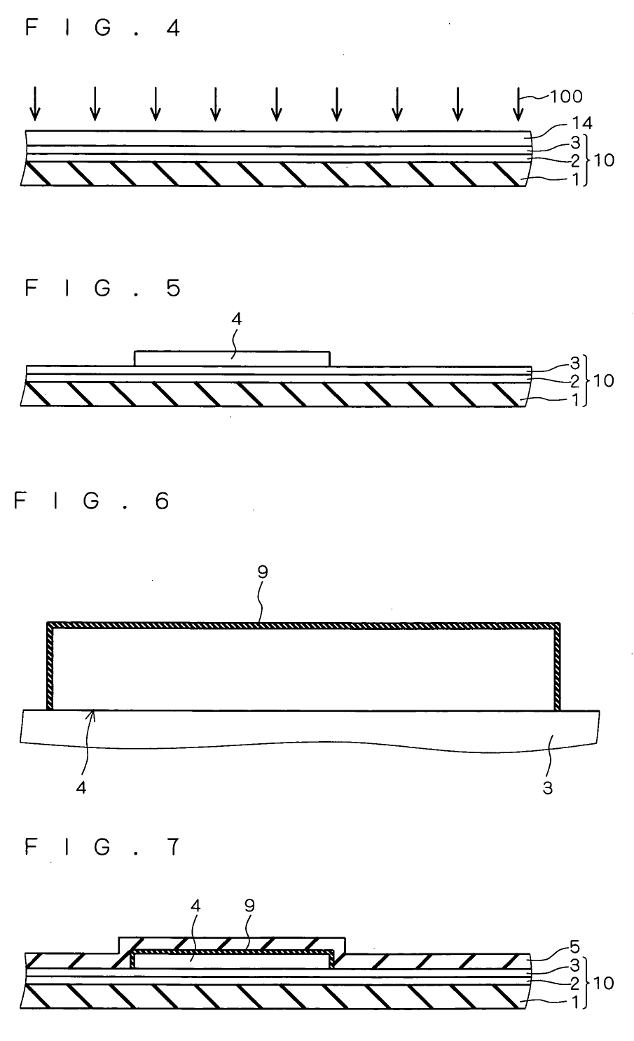

Secondly, as illustrated in FIG. 4, the amorphous silicon film 14 is irradiated with a laser light 100 such as an excimer laser (having a wavelength of 308 nm). At that time, the laser light 100 passes through a preset optical system (not illustrated) and is converted so as to produce a linear beam profile before reaching the amorphous silicon film 14. As a result of such an annealing process using a laser (“laser annealing process”) as described above, the amorphous silicon film 14 is made polycrystalline, to be transformed into the polysilicon film 4.

Additionally, a heat treatment may be further performed in order to reduce the concentration of hydrogen (H) contained in the amorphous silicon film 14 immediately after formation of the amorphous silicon film 14. Performing such a heat treatment would suppress occurrence of a crack which is likely to be caused due to boiling of hydrogen in the amorphous silicon film 14 during the later laser annealing process.

Also, while an excimer laser is employed as the laser light 100 used for making the amorphous silicon film 14 polycrystalline according to the preferred embodiment of the present invention, a YAG laser or a CW (continuous wave) laser may be alternatively employed, for example. Further, a thermal annealing process, instead of a laser annealing process, may be employed for making the amorphous silicon film 14 polycrystalline. In a case where a thermal annealing process is employed, it is possible to form a polysilicon film having a greater grain size by using nickel (Ni) as a catalyst.

After formation of the polysilicon film 4, a resist film (not illustrated) having a predetermined opening pattern is formed on the polysilicon film 4. Then, the polysilicon film 4 is etched using the resist film as a mask, to remove a portion of the polysilicon film 4, so that the polysilicon film 4 has a predetermined shape. Thereafter, the resist film is removed. As a result, the polysilicon film 4 is formed on a region of the insulating layer 10 as illustrated in FIG. 5.

Then, a structure illustrated in FIG. 5 is placed within a vacuum chamber of a plasma generation apparatus (not illustrated), such as a plasma CVD apparatus, and an ammonium (NH₃) gas and a nitrogen (N₂) gas are introduced into the vacuum chamber at flow rates of 1 SLM and 3 SLM, respectively. Subsequently, a pressure within the vacuum chamber is set at 200 Pa and an electric power of 100 W is supplied between two electrodes generating plasma. By doing so, plasma is generated within the vacuum chamber, and an exposed surface of the polysilicon film 4 is processed by the generated plasma. As a result, a dangling bond of a silicon atom existing in the surface of the polysilicon film 4 is terminated with a nitrogen atom, and at the same time, a hydrogen atom which has a weak bonding strength and has terminated the dangling bond is replaced with the nitrogen atom. Consequently, the insulating layer 9 including a silicon nitride (SiN) layer containing a silicon atom, a dangling bond of which is terminated with a nitrogen atom, is provided in the surface of the polysilicon film 4, as illustrated in FIG. 6.

On the other hand, to terminate the dangling bond of a silicon atom existing in the surface of the polysilicon film 4 with an ON group, a nitrogen oxide (N₂O) gas and a nitrogen (N₂) gas are introduced into the above-described vacuum chamber in which the structure illustrated in FIG. 5 is placed, at flow rates of 1 SLM and 3 SLM, respectively. Also, the pressure within the vacuum chamber is set at 200 Pa, and an electric power of 100 W is supplied between two electrodes generating plasma. By doing so, plasma is generated within the vacuum chamber, and an exposed surface of the polysilicon film 4 is processed by the generated plasma. As a result, a dangling bond of a silicon atom existing in the surface of the polysilicon film 4 is terminated with an ON group, and at the same time, a hydrogen atom which has a weak bonding strength and has terminated the dangling bond is replaced with the ON group. Consequently, the insulating layer 9 including a silicon oxynitride (SiON) layer containing a silicon atom, a dangling bond of which is terminated with an ON group, is provided in the surface of the polysilicon film 4.

Additionally, the dangling bond of a silicon atom exiting in the surface of the polysilicon film 4 can be terminated with an ON group in the following alternative manner. Specifically, the structure illustrated in FIG. 5 is placed in a furnace filled with water vapors having a temperature of 500° C., in which a pressure is set to 0.2 MPa, and is left unattended for approximately one hour, to form a thin silicon oxide film in the surface of the polysilicon film, first. Thereafter, the resultant structure is subjected to a heat treatment in a nitrogen atmosphere and at a temperature of approximately 500° C.

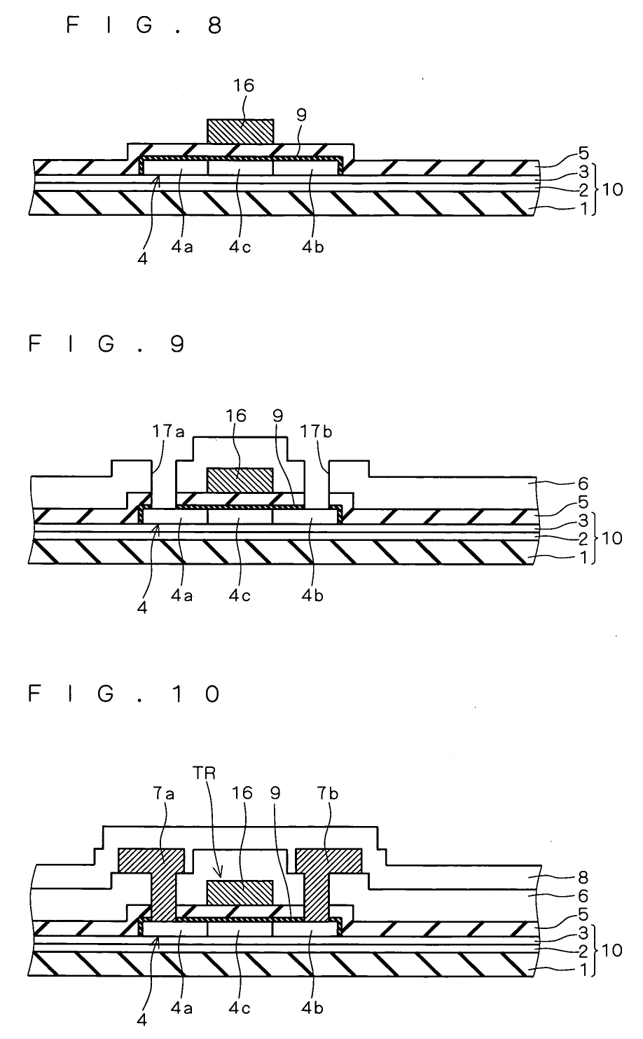

Turning back to the figures, as illustrated in FIG. 7, the gate insulating film 5 having a thickness of approximately 100 nm, for example, is formed on the insulating layer 10 so as to cover the polysilicon film 4 and the insulating layer 9. For formation of the gate insulating film 5, a structure illustrated in FIG. 6, in which the insulating layer 9 is formed in the surface of the polysilicon film 4, is subjected to a CVD process or the like without exposing the structure illustrated in FIG. 6 to the atmosphere. For example, with the structure illustrated in FIG. 6 being placed within the vacuum chamber of the above-described plasma generation apparatus after the insulating layer 9 is formed, the insulating substrate 1 is heated so that the insulating substrate 1 has a temperature of 350° C., first. Subsequently, a TEOS gas and an oxygen (O₂) gas are introduced into the vacuum chamber at flow rates of 0.1 SLM and 5 SLM, respectively. Then, the pressure within the vacuum chamber is set at 150 Pa, and an electric power of 2000 W is supplied between two electrodes generating plasma. By doing so, plasma discharge occurs, so that the gate insulating film 5 including a silicon oxide film is formed on the polysilicon film 4 and the insulating layer 9 without exposing the polysilicon film 4 and the insulating layer 9 to the atmosphere.

After formation of the gate insulating film 5, a conductive film which is to serve as the gate electrode 16 is formed on the gate insulating film 5 by a sputtering process, for example. Subsequently, a resist film (not illustrated) having a predetermined opening pattern is formed on the conductive film, and the conductive film is etched using the resist film as a mask, to remove a portion of the conductive film. Thereafter, the resist film is removed. As a result, the gate electrode 16 is formed on a region of the gate insulating film 5 as illustrated in FIG. 8.

After formation of the gate electrode 16, phosphorus is implanted into the polysilicon film 4 from above at a predetermined dose by an ion doping process. At that time, the gate electrode 16 serves as a mask, so that phosphorus is implanted into opposite edge portions of the polysilicon film 4. As a result, the n-type source region 4a and the n-type drain region 4b are formed in the polysilicon film 4 with a predetermined distance being left therebetween and a portion of the polysilicon film 4 which is interposed between the source region 4a and the drain region 4b forms the channel region 4c, as illustrated in FIG. 8.

Then, the interlayer insulating film 6 is formed on the gate insulating film 5 so as to cover the gate electrode 16 as illustrated in FIG. 9, and the resultant structure is subjected to a heat treatment at a temperature of approximately 450° C. The heat treatment activates ions implanted into the polysilicon film 4, in other words, ions contained in the source region 4a and the drain region 4b. Thereafter, a resist film (not illustrated) which has a predetermined opening pattern is formed on the interlayer insulating film 6, and the interlayer insulating film 6 is etched using the resist film as a mask. Also, the gate insulating film 5, and subsequently, the insulating layer 9, are etched using the resist film as a mask. After that, the resist film is removed. As a result, contact holes 17a and 17b which pass through the interlayer insulating film 6, the gate insulating film 5, and the insulating layer 9 and reach the source region 4a and the drain region 4b, respectively, are formed in the interlayer insulating film 6, the gate insulating film 5, and the insulating layer 9, as illustrated in FIG. 9.

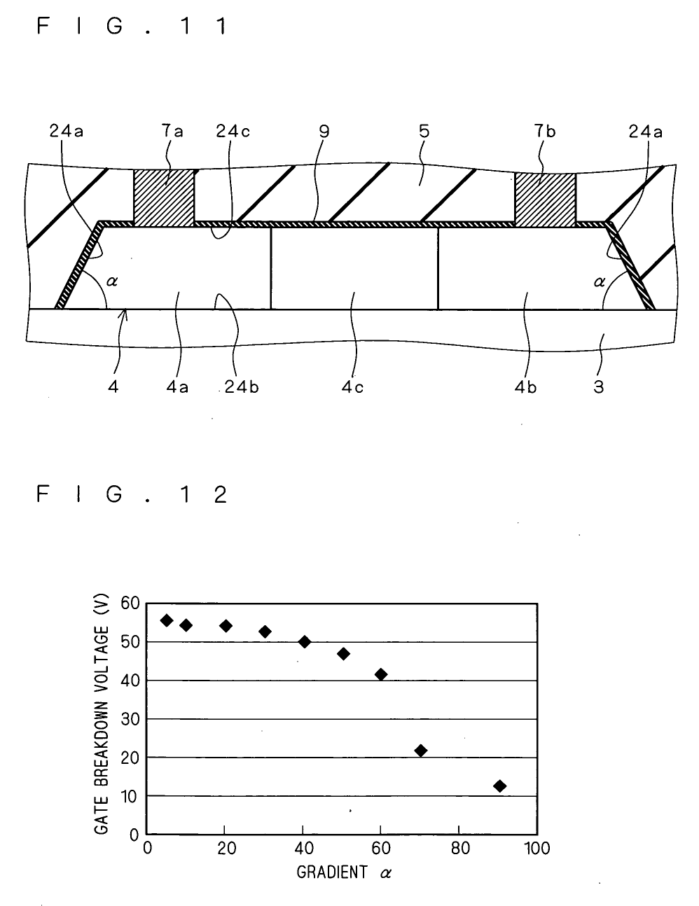

After formation of the contact holes 17a and 17b, the source electrode 7a and the drain electrode 7b are formed on the interlayer insulating film 6, and at the same time, the contact holes 17a and 17b are filled with the source electrode 7a and the drain electrode 7b, respectively, as illustrated in FIG. 10. Then, the thin-film transistor TR is completed.

Thereafter, the insulating film 8 is formed on the interlayer insulating film 6 so as to cover the source electrode 7a and the drain electrode 7b which are exposed, by a plasma CVD process, for example. Subsequently, a resist film (not illustrated) which has a predetermined opening pattern is formed on the insulating film 8, and the insulating film 8 is etched using the resist film as a mask, to remove a portion of the insulating film 8. Thereafter, the resist film is removed. As a result, the contact hole 11 which passes through the insulating film 8 and reaches the drain electrode 7b is, formed in the insulating film 8. Then, the semiconductor device illustrated in FIG. 1 is completed.

As described above, in the method of manufacturing a semiconductor device according to the preferred embodiment of the present invention, the dangling bond of a silicon atom existing in the surface of the polysilicon film 4 is terminated with a nitrogen atom or an ON group. It is repeated that as a bonding energy provided between a silicon atom and a nitrogen atom is greater than a bonding energy provided between a silicon atom and a hydrogen atom, a bond between a silicon atom and a nitrogen atom is not easily broken. It is also repeated that as a bonding energy provided between a silicon atom and an ON group is greater than a bonding energy provided between a silicon atom and a hydrogen atom, a bond between a silicon atom and an ON group is not easily broken. For this reason, even in continuous operation of the thin-film transistor TR, changes in the transistor characteristics such as reduction of an on-state current and a change in a threshold voltage can be suppressed, to thereby improve the performance of the thin-film transistor TR.

Also, in the method of manufacturing a semiconductor device according to the preferred embodiment of the present invention, the gate insulating film 5 is formed on the polysilicon film 4 without exposing the structure resulted from terminating the dangling bond of a silicon atom existing in the surface of the polysilicon film 4 with a nitrogen atom or an ON group, to the atmosphere. This makes it possible to avoid an unstable bond between the polysilicon film 4 and oxygen or nitrogen which is likely to occur due to inclusion of oxygen or nitrogen in the atmosphere. As a result, it is possible to obtain the thin-film transistor TR with a higher reliability.

Alternatively, an LDD (lightly doped drain) structure may be additionally included in the thin-film transistor TR according to the preferred embodiment of the present invention. Such LDD structure can be provided by forming an impurity region which is of the same conductivity type as the source region 4a and the drain region 4b and has a lower impurity concentration than that of the source region 4a and the drain region 4b in each of portions of the polysilicon film 4 according to the above-described preferred embodiment, which portions are located between the source region 4a and the channel region 4c and between the drain region 4b and the channel region 4c, respectively.

Further alternatively, the polysilicon film 4 may be formed so as to have a slanted side face, in other words, to have a tapered sectional shape in which the width of the polysilicon film 4 becomes smaller as a distance to the gate insulating film 5 decreases. FIG. 11 is an enlarged sectional view of a portion of a structure of the semiconductor device according to the preferred embodiment of the present invention in a case where the foregoing modification is made. As illustrated in FIG. 11, an angle between a side face 24a and a bottom face 24b, in other words, a gradient α, is controlled to be equal to or smaller than 60 degrees in the polysilicon film 4. By doing so, a breakdown voltage of the gate (“gate breakdown voltage”) of the thin-film transistor TR can be improved. Such effects will be described in detail below.

For example, when a glass substrate is employed as the insulating substrate 1, a process temperature for formation of the semiconductor device cannot be set at 550° C. or higher in order to prevent distortion or shrinkage of the glass substrate, as generally known. For this reason, a silicon oxide film formed by a plasma CVD process in an atmosphere having a low temperature in a range of 30° to 400° C. is employed as the gate insulating film 5 in most cases. Such silicon oxide film as formed by a plasma CVD process, however, has a drawback of a poor step coverage as generally known. Thus, when the polysilicon film 4 is formed and processed so as to include the side face 24a and the bottom face 24b which are perpendicular to each other, a difference in thickness of the gate insulating film 5 which is to be formed on the polysilicon film 4 would probably be caused. Specifically, a portion on a corner between a top face 24c and the side face 24a of the polysilicon film 4 is thinner than a portion on the top face 24c of the polysilicon film 4, in the gate insulating film 5. Also, when the polysilicon film 4 is formed so as to be thick, the portion of the gate insulating film 5 on the forgoing corner of the polysilicon film 4 is extremely thin. For example, when the polysilicon film 4 is formed so as to have a thickness of 50 nm and to include the side face 24a and the bottom face 24b which are perpendicular to each other and the gate insulating film 5 is formed on the polysilicon film 4 by a plasma CVD process using a silicon oxide film having a thickness of 100 nm, the thickness of the portion of the gate insulating film 5, which portion is provided on the foregoing corner of the polysilicon film 4, is approximately 70 nm.

On the other hand, the gate breakdown voltage of the thin-film transistor TR which is governed by a breakdown voltage between the gate electrode 16 and the source electrode 7a depends on a thickness of the gate insulating film 5. If the gate insulating film 5 includes a portion which is relatively thin as described above, the gate breakdown voltage of the thin-film transistor TR is reduced. FIG. 12 is a graph which shows a relationship between the gradient α of the polysilicon film 4 and the gate breakdown voltage of the thin-film transistor TR. The graph of FIG. 12 shows experimental results provided when the polysilicon film 4 is formed so as to have a thickness of 50 nm and a silicon oxide film having a thickness of 100 nm is formed as the gate insulating film 5 by a plasma CVD process.

As shown in FIG. 12, when the gradient α exceeds 60 degrees, the gate breakdown voltage abruptly reduces. Accordingly, by setting the gradient α at 60 degrees or smaller, it is possible to improve the gate breakdown voltage of the thin-film transistor TR.

Even when the gradient α is larger than 60 degrees, the gate breakdown voltage can be improved by increasing the thickness of the gate insulating film 5 which is to be formed. For example, consider a situation where the semiconductor device according to the present invention is employed for a liquid crystal display. In this case, a gate voltage of the thin-film transistor TR is usually set at 10 V and a margin of approximately 10 V for the gate voltage is required, so that the gate breakdown voltage of the thin-film transistor TR must be equal to or larger than 20 V. The gate breakdown voltage of 20 V or larger can be easily obtained by forming the gate insulating film 5 so as to have a thickness of 120 nm. However, to increase the thickness of the gate insulating film 5 is not preferable because to do so causes reduction in an on-state current of the thin-film transistor TR. The on-state current of the thin-film transistor TR, in other words, a drain current Id in a saturation region, is expressed by the following equation (1).
Id=W×μCox×(Vg−Vth)²/(2L) (1)
wherein W represents a gate width, μ represents a mobility, Vg represents a gate voltage, Vth represents a threshold voltage, L represents a gate length, and Cox represents a gate capacitance per unit area. When the thickness of the gate insulating film 5, a relative dielectric constant of the gate insulating film 5, and a dielectric constant in a vacuum are represented by d, εs, and ε0, respectively, Cox can be expressed by the following equation (2):
Cox=ε0×εs/d (2).

It is appreciated from the equation (2) that as the thickness d of the gate insulating film 5 increases, Cox decreases. The decrease of Cox will lead to reduction of the drain current Id as indicated by the equation (1). Accordingly, increase of the thickness of the gate insulating film 5 will cause reduction of the on-state current of the thin-film transistor TR. Thus, it is not suitable for practical use to increase the thickness of the gate insulating film 5 for the purpose of improving the gate breakdown voltage.

Furthermore, it is preferable that the gradient α of the polysilicon film 4 is equal to or smaller than 60 degrees and is equal to or larger than 5 degrees. By setting the gradient α as such, it is possible to not only improve the gate breakdown voltage but also keep a size of the thin-film transistor TR to a practical level.

For example, in a case where the thickness of the polysilicon film 4 is 50 nm and the gradient α is 5 degrees, a length of one side of the side face 24a of the polysilicon film 4, which side is parallel to the insulating substrate 1 in plan view, is approximately 0.6 μm. Assuming that each of a length and a width of the top face 24c of the polysilicon film 4 is 5 μm, an area of the side face 24a of the polysilicon film 4 in plan view is 6 μm² (=0.6×(5+5)), and an area of the top face 24c is 25 μm². As such, in the case where the gradient α is set at 5 degrees, a surface area of the polysilicon film 4 in plan view is increased by 24% (=6/25×100) as compared to the case where the gradient α is set at 90 degrees. By further decreasing the gradient α from 5 degrees to 4 degrees, the length of the side of the side face 24a of the polysilicon film 4, which side is parallel to the insulating substrate 1 in plan view, is increased to approximately 0.7 μm, so that the area of the side face 24a of the polysilicon film 4 in plan view is 7 μm² (=0.7×(5+5)). Accordingly, in the case where the gradient α is set at 4 degrees, the surface area of the polysilicon film 4 in plan view is increased by 28% (=7/25×100) as compared to the case where the gradient α is set at 90 degrees.

As is made clear from the above description, setting the gradient α at 5 degrees will lead to a 24% increase of the surface area of the polysilicon film 4 in plan view, and setting the gradient α at 4 degrees will lead to a 28% increase of the surface area of the polysilicon film 4 in plan view, as compared to the case where the gradient α is set at 90 degrees. Considering the practical size of the thin-film transistor TR, it is desirable that the surface area of the polysilicon film 4 in plan view is increased by 25% or less as compared to the case where the gradient α is set at 90 degrees. As such, by setting the gradient α at any value in a range of 5 to 60 degrees, it is possible to not only keep the size of the thin-film transistor TR to a practical level, but also improve the gate breakdown voltage.

To form the polysilicon film 4 so as to have a tapered sectional shape in which the width of the polysilicon film 4 becomes smaller as a distance to the gate insulating film 5 decreases as illustrated in FIG. 11, a reactive ion etching (RIE) process which utilizes the above-mentioned “resist diminishing method” is performed on the polysilicon film 4 after the amorphous silicon film 14 is transformed into the polysilicon film 4 (refer to FIG. 4). The gradient α of the polysilicon film 4 can be controlled by adjusting a mixing ratio of an etching gas used in the reactive ion etching process, in particular, a flow rate of an oxygen gas. To set the gradient α at 20 degrees, for example, a mixed gas including CF₄ and O₂, respective flow rates of which are set at 200 cm³/min(sccm) and 100 cm³/min(sccm), is employed, a pressure of an etching gas is set at 15 Pa, and an RF power of an apparatus for the reactive ion etching process is set at 1500 W.

In this manner, it is possible to easily slant the side face 24a of the polysilicon film 4 with use of the resist diminishing method.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device including a transistor, comprising:
a polysilicon film in which a source region and a drain region of said transistor are formed;
a gate insulating film of said transistor which is formed on said polysilicon film; and
a gate electrode of said transistor which is formed on said gate insulating film, wherein
a first insulating layer containing a silicon atom, a dangling bond of which is terminated with a nitrogen atom or an ON group, is provided in an interface between said polysilicon film and said gate insulating film.

2. A semiconductor device including a transistor, comprising:
a polysilicon film in which a source region and a drain region of said transistor are formed;
a gate insulating film of said transistor which is formed on said polysilicon film; and
a gate electrode of said transistor which is formed on said gate insulating film, wherein
said polysilicon film has a tapered sectional shape in which a width of said polysilicon film becomes smaller as a distance to said gate insulating film decreases, and
a gradient of said polysilicon film is equal to or smaller than 60 degrees.

3. The semiconductor device according to claim 2, wherein
said gradient is in a range of 5 to 60 degrees.

4. The semiconductor device according to claim 1, wherein
said polysilicon film is formed on a second insulating layer including a glass substrate, and
said gate insulating film is a silicon oxide film.

5. The semiconductor device according to claim 2, wherein
said polysilicon film is formed on an insulating layer including a glass substrate, and
said gate insulating film is a silicon oxide film.

6. A method of manufacturing a semiconductor device including a transistor, comprising the steps of:
(a) forming a polysilicon film;
(b) terminating a dangling bond of a silicon atom existing in a surface of said polysilicon film with a nitrogen atom or an ON group;
(c) forming a gate insulating film of said transistor on said polysilicon film after said step (b);
(d) forming a source region and a drain region of said transistor in said polysilicon film; and
(e) forming a gate electrode of said transistor on said gate insulating film.

7. The method of manufacturing a semiconductor device according to claim 6, wherein
said gate insulating film is formed on said polysilicon film without exposing a structure resulted from performance of said step (b) to the atmosphere, in said step (c).
